(19) United States
(12) Patent Application Publication
(10) Pub. No.: US 2026/0341641 A1
(43) Pub. Date: Oct. 29, 2026

(54) SYSTEMS AND METHODS FOR FAST CONTROL OF IMPEDANCE ASSOCIATED WITH AN OUTPUT OF A PLASMA SOURCE

(71) Applicant: Lam Research Corporation, Fremont, CA (US)

(72) Inventor: Sanghyeon Park, Sunnyvale, CA (US)

(21) Appl. No.: 19/122,236

(22) PCT Filed: Oct. 20, 2023
(86) PCT No.: PCT/US23/77474

§ 371 Date: Apr. 17, 2025

Related U.S. Application Data
(60) Provisional application No. 63/418,876, filed on Oct. 24, 2022.

(51) Int. Cl. H01J 37/32

(52) U.S. Cl. CPC H01J 37/32183

(57) ABSTRACT

Systems and methods for fast control of impedance associated with an output of a plasma source are described. One of the systems includes the plasma source that generates a radio frequency (RF) signal. The system further includes a load coupled to the plasma source via an RF connection. The RF connection has a point. The system further includes a tunable impedance match coupled to the point between the plasma source and the load. The tunable impedance match includes a dependent voltage source and a circuit network. The dependent voltage source is coupled in series with the circuit network. The tunable impedance match modifies an impedance of the RF signal to output a modified RF signal, which is provided to the load.

### FIELD

The present embodiments relate to systems and methods for fast control of impedance associated with an output of a plasma source.

### BACKGROUND

In a plasma tool, there is radio frequency (RF) generator. The RF generator is coupled via a match to a plasma chamber. A wafer is placed inside the plasma chamber for processing. The RF generator generates an RF signal and supplies the RF signal to the match. The match matches an output impedance with an input impedance to output an RF signal towards the plasma chamber. The RF signal is used to generate plasma for processing the wafer. However, it is difficult to operate the RF generator or the match in a desirable manner.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for fast control of impedance associated with an output of a plasma source. It should be appreciated that the present embodiments can be implemented in numerous ways, e.g., a process, an apparatus, a system, a device, or a method on a computer readable medium. Several embodiments are described below.

In an embodiment, an effective impedance of an inductor-capacitor (LC) network changes quickly with a gain of a dependent voltage source (DVS). An example of the effective impedance is an impedance from the standpoint of the DVS.

In an embodiment, an alternating current (AC) voltage source, such as the DVS, represents a switch-mode inverter, e.g., a power amplifier. For zero-voltage switching (ZVS), the switch-model inverter drives a resistive or inductive impedance.

In one embodiment, a tunable impedance match is provided. The tunable impedance match allows fast impedance matching for radio frequency (RF) generators driving a variable plasma load. To achieve the fast impedance matching, a variable plasma load impedance is matched to a desired impedance, which is 50 ohms. The tunable impedance match enhances or replaces an impedance matching circuit that includes one or more mechanically variable vacuum capacitors, each of which is adjusted by a stepper motor. The impedance matching circuit operates in a millisecond or longer timescale to complete impedance tuning. The tunable impedance match can complete impedance tuning, such as impedance matching, in tens of microseconds timescale. The microsecond timescale that is used to track plasma load variation during a capacitive coupling (E-mode) strike, the capacitive coupling to an inductive coupling transition (E-to-H transition), and many other plasma load variations encountered while processing semiconductor wafers. This orders-of-magnitude improvement in tuning speed increases a performance of an RF power system.

In an embodiment, a tunable impedance match including one or more dependent voltage sources connected to an inductor-capacitor (LC) network is provided. The tunable impedance match includes a dependent voltage source, which includes a half-bridge direct current-to-RF (DC-to-RF) inverter. The half-bridge DC-to-RF inverter drives a series inductor of the tunable impedance match. In this configuration, an apparent inductance seen from an end of the series inductor is inversely proportional to a voltage gain of the dependent voltage source. Therefore, the apparent inductance can be modified by changing a voltage gain of the dependent voltage source. An actual circuit implementation achieves the change in the voltage gain by either the half-bridge DC-to-RF inverter powered by a variable DC supply voltage, also known as an agile rail or by outphasing control, which is a control of phases.

In one embodiment, a system for fast control of impedance associated with an output of a plasma source is described. The system includes the plasma source that generates a RF signal. The system further includes a load coupled to the plasma source via an RF connection. The RF connection has a point. The system further includes a tunable impedance match coupled to the point between the plasma source and the load. The tunable impedance match includes a dependent voltage source and a circuit network. The circuit network includes a capacitor or an inductor or a combination thereof. The dependent voltage source is coupled in series with the circuit network. The tunable impedance match modifies an impedance of the RF signal to output a modified RF signal, which is provided to the load.

In one embodiment, a system for control of impedance associated with an output of a plasma source is described. The system includes the plasma source that generates an RF signal, and a load coupled to the plasma source via an RF connection. The RF connection has a point. The system further includes a plurality of tunable impedance matches coupled to the point between the plasma source and the load. The plurality of tunable impedance matches include a first tunable impedance match and a second tunable impedance match. The first tunable impedance match includes a first dependent voltage source and a first circuit network. The second tunable impedance match includes a second dependent voltage source and a second circuit network. The first circuit network includes a first capacitor or a first inductor or a combination thereof. The first dependent voltage source is coupled in series with the first circuit network. The second circuit network includes a second capacitor or a second inductor or a combination thereof. The second dependent voltage source is coupled in series with the second circuit network. The plurality of tunable impedance matches modify an impedance of the RF signal to output a modified RF signal. The modified RF signal is provided to the load.

In an embodiment, a system for control of impedance associated with an output of an RF generator is described. The system includes the RF generator that generates an RF signal, and includes a tunable impedance match coupled to the RF generator via an RF cable to receive the RF signal. The tunable impedance match includes a dependent voltage source. The tunable impedance match modifies an impedance of the RF signal to output a modified RF signal. The system includes a load coupled to the tunable impedance match via an RF transmission line to receive the modified RF signal.

Several advantages of the herein described systems and methods for fast control of impedance associated with an output of a plasma source include quick modification of impedance of an RF signal generated by a plasma source. A tunable impedance match is provided. The tunable impedance match includes a direct current (DC) voltage source and multiple pulse signal sources. A DC voltage of the DC voltage source or phases of pulse signals that are generated by the pulse signal sources or a combination thereof are modified to output a modified waveform. The modified waveform modifies the impedance of the RF signal generated by the plasma source in a quick and efficient manner. The impedance is modified quickly compared to when an impedance matching circuit with only mechanical components is used.

The herein described systems and methods have a lower system complexity and potentially a lower build cost because two power transistors are used for implementation in the tunable impedance match. Also, a reactance can be adjusted continuously, allowing accurate impedance matching. Compared to the mechanically varied vacuum capacitors, the systems and methods speed up the impedance tuning speed by more than 100 times. This faster tuning speed enhances the reliability of the RF system because RF generators operate for a significantly shorter time under undesirable non-matched impedance conditions. Moreover, the RF power system's accurate and real-time tracking of plasma load variation will allow development of new semiconductor processes that are currently under-explored due to slow impedance tuning speed.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate use of a tunable impedance match.

FIG. 2 is a diagram of an embodiment of a dependent voltage source (DVS).

FIG. 3A is a diagram of an embodiment of a system to illustrate an inductor-capacitor (LC) network.

FIG. 3B is a diagram of an embodiment of a system to illustrate another LC network.

FIG. 3C is a diagram of an embodiment of a system to illustrate yet another LC network.

FIG. 3D is a diagram of an embodiment of a system to illustrate still another LC network.

FIG. 3E is a diagram of an embodiment of a system to illustrate another LC network.

FIG. 3F-1 is a diagram of an embodiment of a system to illustrate multiple tunable impedance matches.

FIG. 3F-2 is a diagram of an embodiment of a system to illustrate details of the DVSs of FIG. 3F-1.

FIG. 4A is a diagram of an embodiment of a system to illustrate use of multiple DVSs within a match.

FIG. 4B is a diagram of an embodiment of a system to illustrate use of multiple DVSs within another match.

FIG. 5 is a diagram of an embodiment of a system to illustrate use of a DVS and an LC network with mechanical components of a hybrid match.

FIG. 6 is a diagram of an embodiment of a graph to illustrate an operation of the hybrid match.

### DETAILED DESCRIPTION

The following embodiments describe systems and methods for fast control of impedance associated with an output of a plasma source. It will be apparent that the present embodiments may be practiced without some or all of these specific details. In other instances, well known operations have not been described in detail in order not to unnecessarily obscure the present embodiments.

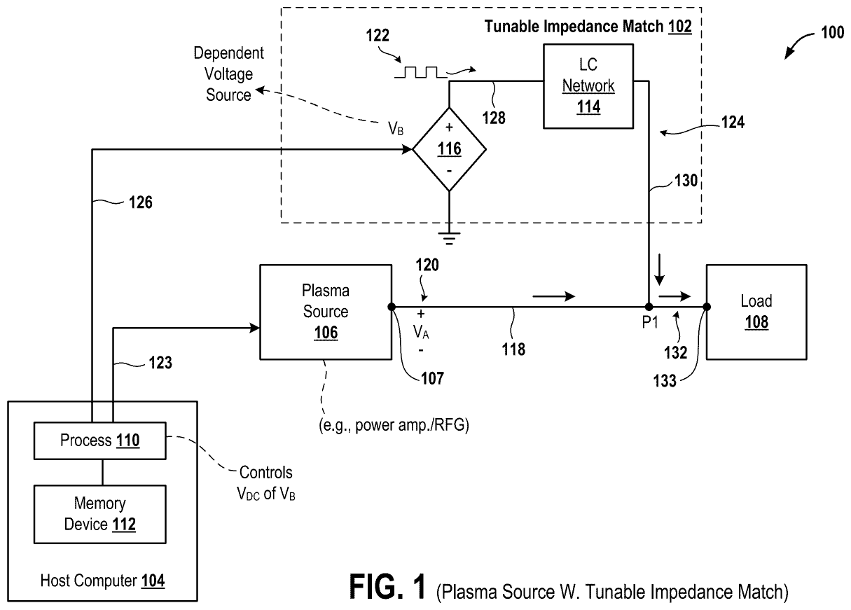

FIG. 1 is a diagram of an embodiment of a system 100 to illustrate use of a tunable impedance match 102. The system 100 includes the tunable impedance match 102, a host computer 104, a plasma source 106, and a load 108. Examples of a host computer, as used herein, include a desktop computer, a controller, laptop computer, a tablet, and a smart phone.

The plasma source 106 includes a combination of a matchless plasma source and a reactive circuit, or includes a radio frequency (RF) generator. Examples of the reactive circuit include a capacitor and an inductor. To illustrate, the reactive circuit includes a single capacitor or a single inductor. The reactive circuit is coupled to the matchless plasma source. When the plasma source 106 is the matchless plasma source or the RF generator, there is no match, such as an impedance matching circuit or an impedance matching network, other than the tunable impedance match 102, between the plasma source 106 and the load 108, and the load 108 includes a plasma chamber.

The host computer 104 includes a processor 110 and a memory device 112. As an example, the processor 110 is an application specific integrated circuit (ASIC), a central processing unit (CPU), a field programmable gate array (FPGA), a microprocessor, a programmable logic device (PLD), an integrated controller, or a microcontroller. Examples of the memory device 112 include a read-only memory (ROM) and a random access memory (RAM). To illustrate, the memory device 112 is a flash memory or a redundant array of independent discs (RAID). The processor 110 is coupled to the memory device 112.

The tunable impedance match 102 includes an inductor-capacitor (LC) network 114 and a dependent voltage source (DVS) 116. The processor 110 is coupled to the plasma source 106 and to the DVS 116. The dependent voltage source 116 is coupled to the LC network 114, which is coupled to a point P1 on an RF connection 118. The RF connection 118 couples an output 107 of the plasma source 106 to an input 133 of the load 108.

The point P1 is located between the plasma source 106 and the load 108. For example, the point P1 is located between the output 107 and the input 133. An example of the point Pl is a connector that connects the RF connection 118 to an RF connection 130. Another example of the point P1 is a soldered connection between the RF connections 118 and 130. An example of the RF connection 118 includes one or more conductors for transferring RF signals when the plasma source 106 is the matchless plasma source. When the plasma source 106 is the matchless plasma source, the RF connection 118 does not include a 50-ohm RF cable. Another example of the RF connection 118 includes the 50-ohm RF cable when the plasma source 106 is the RF generator. Yet another example of the RF connection 118 includes a combination of the 50-ohm RF cable and an RF transmission line. To illustrate, the RF connection 118 includes the 50-ohm RF cable from the output 107 to the point P1 and includes the RF transmission line from the point P1 to the electrode. The RF transmission line is further described below.

The processor 110 is coupled to the plasma source 106 and to the DVS 116. For example, the processor is coupled to the plasma source 106 via a transfer cable 123 and to the DVS 116 via another transfer cable 126. Examples of a transfer cable, as used herein, include a cable for transferring data in a serial manner, a cable for transferring data in a parallel manner, and a cable for transferring data using a Universal Serial Bus (USB) protocol. The DVS 116 is coupled to the LC network 114 via an RF connection 128 to be coupled in series with the RF connection 128, and the LC network is coupled to the point P1 via the RF connection 130.

The processor 110 controls the plasma source 106 to generate an RF signal 120 and supply the RF signal 120 to the load 108. For example, the processor 110 sends a phase, a frequency, and an amplitude of a voltage of the RF signal 120 via the transfer cable 123 to the plasma source 106. Upon receiving the phase, the frequency, and the amplitude, the plasma source 106 generates the voltage of the RF signal 120 having the phase, the frequency, and the amplitude. When the RF signal 120 is generated, a voltage at the output 107 of the plasma source 106 with respect to a ground potential is V_{A}. For example, a voltage of the RF signal 120 is V_{A}.

Moreover, the processor 110 controls the DVS 116 to generate a square waveform 122 at the radio frequency. Also, by controlling the DVS 116, fast control of an impedance of the square waveform 122 output from the DVS 116 is achieved. The DVS 116 generates the square waveform 122 and supplies the square waveform 122 to the LC network 114. The LC network 114 modifies an impedance of the square waveform 122 to output a modified waveform 124, and provides the modified waveform 124 to the point P1. The LC network 114 includes only electronic components, such as one or more electronic inductors, or one or more electronic capacitors, or a combination thereof, to achieve fast control, such as modification, of the square waveform 122 to output the modified waveform 124. Examples of the electronic components are provided below. The modified waveform 124 has a sinusoidal shaped at the radio frequency. When the square waveform 122 is generated, a voltage at or output from the DVS 116 with respect to the ground potential is V_{B}. For example, a voltage of the square waveform 122 is V_{B}.

The modified waveform 124 is combined with the RF signal 120 at the point P1 to generate an RF signal 132, which is provided to the load 108 for processing a semiconductor substrate, such as a wafer, within the plasma chamber. For example, power of the RF signal 120 is summed with power of the modified waveform 124 to output power of the RF signal 132.

The RF signal 132 is transferred via the RF connection 118 to an electrode, such as an RF coil or an upper electrode or an electrostatic chuck (ESC), of the plasma chamber. When the plasma chamber is a capacitively coupled plasma (CCP) chamber, the plasma chamber includes the upper electrode and the ESC. Also, when the plasma chamber is an inductively coupled plasma (ICP) chamber, the plasma chamber includes the RF coil and the ESC.

It should be noted that when the load 108 is resistive or inductive, the processor 110 controls the DVS 116 to remain off, e.g., inoperational, etc., or substantially off. For example, the processor controls the DVS 116 to output the voltage V_{B} of zero volts to remain off. As another example, the processor controls the DVS 116 to output the voltage V_{B} within a pre-determined range, such as 5% to 10% from zero volts, for the DVS 116 to remain substantially off. Also, when DVS 116 is substantially off or off, the processor 110 controls the plasma source 106 to provide the RF signal 120 to the load 108. The RF signal 108 provides most of a current to the load 108. On the other hand, when the load 108 is resistive or capacitive, the processor 110 controls the DVS 116 to remain on, e.g., operational, to provide most of a capacitive current. For example, the processor controls the DVS 116 to output the voltage V_{B} greater than the pre-determined range from zero volts. Also, when the DVS 116 is on, the processor 110 controls the plasma source 106 to provide most of a resistive current. For example, the processor 110 controls the plasma source 106 to generate the RF signal 120 having most of the resistive current.

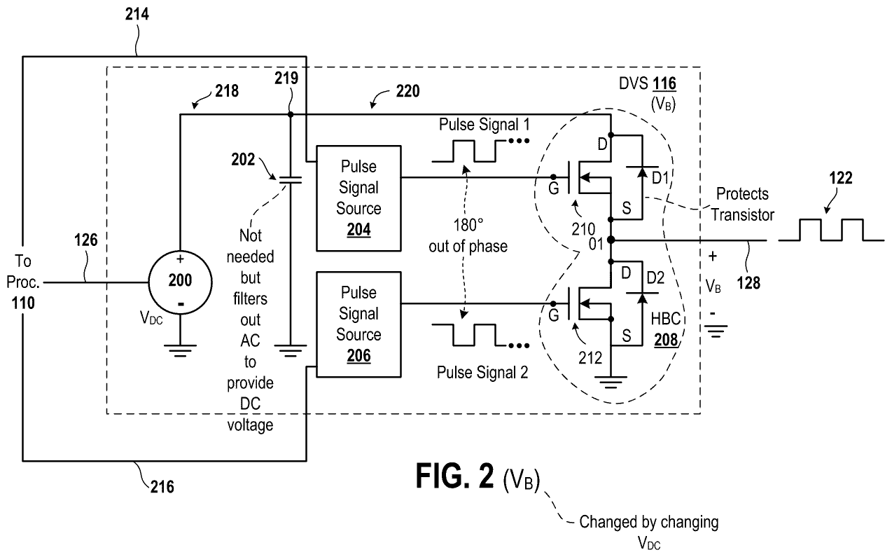

FIG. 2 is a diagram of an embodiment of the DVS 116. The DVS 116 includes a direct current (DC) voltage source 200, a capacitor 202, a pulse signal source 204, another pulse signal source 206, and a half-bridge circuit (HBC) 208. A half-bridge circuit, described herein, is sometimes referred to herein as a half-bridge DC-to-RF inverter and is an example of an inverter circuit. An example of a pulse signal source, as used herein, is a digital pulse signal source, such as a clock oscillator. The HBC 208 includes a transistor 210, another transistor 212, a diode D1, and another diode D2. Each transistor 210 and 212 is a metal-oxide semiconductor field-effect transistor (MOSFET). For each transistor 210 and 212 has a gate (G), a source(S), and a drain (D).

The DC voltage source 200 is coupled at one end to the transfer cable 126, is coupled via a point 219 to the capacitor 202, and is coupled via the point 219 to the drain of the transistor 210. Another end of the DC voltage source 200 is coupled to the ground potential. The capacitor 202 is coupled at one end to the DC voltage source 200 via the point 219 and at an opposite end to the ground potential.

The source of the transistor 210 is coupled to an output O1, which is coupled to the RF connection 128. The output O1 is coupled to the drain of the transistor 212 and the source S of the transistor 212 is coupled to the ground potential. Because the DC voltage source 200, the capacitor 202, and the HBC 208 are coupled with each other at the same point 219 and also coupled to the ground potential, the DC voltage source 200, the capacitor 202, and the HBC 208 are coupled to each other in parallel. The pulse signal source 204 is coupled to the processor 110 (FIG. 1) via a transfer cable 214 and is coupled to the gate of the transistor 210. Also, the pulse signal source 206 is coupled to the processor 110 via a transfer cable 216 and is coupled to the gate of the transistor 212.

The processor 110 controls the pulse signal source 204 to generate a pulse signal 1. For example, the processor 110 provides a frequency, a phase, and a duty cycle to the pulse signal source 204 via the transfer cable 214. Upon receiving the frequency, the phase, and the duty cycle, the pulse signal source 204 generates the pulse signal 1 having the duty cycle, the phase, and the frequency, and sends the pulse signal 1 to the gate of the transistor 210.

Similarly, upon receiving a duty cycle, phase, and a frequency via the transfer cable 216 from the processor 110, the pulse signal source 206 generates a pulse signal 2 having the duty cycle, the phase, and the frequency. The processor 110 controls the pulse signal 2 to be in reverse synchronization with the pulse signal 1. For example, the processor 110 provides the phase of the pulse signal 2 to be 180 degrees out of phase with the phase of the pulse signal 1. The phase of the pulse signal 2 is provided to the pulse signal source 206. The pulse signal 2 is sent from the pulse signal source 206 to the gate of the transistor 212.

The processor 110 controls the DC voltage source 202 to control an amplitude V_{DC} of a voltage signal 218. For example, the processor 110 provides the amplitude Vc to the DC voltage source 202. Upon receiving the amplitude V_{DC}, the DC voltage source 200 outputs the voltage signal 218 having the amplitude V_{DC} towards the drain of the transistor 210. The capacitor 202 filters out an alternating current (AC) signal from the voltage signal 218 to provide a voltage signal 220 to the drain of the transistor 210.

The voltage signal 220 has the substantially the same, such as the same, amplitude as that of the voltage signal 218. For example, the voltage signal 220 has the amplitude V_{DC} that is equal to the amplitude of the voltage signal 218. As another example, the voltage signal 220 has an amplitude that is a difference between the amplitude V_{DC} of the voltage signal 218 and amplitudes of the AC signal that is filtered out. When the voltage signal 220 is provided to the transistor 210, the transistors 210 and 212 operate in a push-pull mode based on the pulse signals 1 and 2 to provide the square waveform 122 at the output O1. For example, in the push-pull mode, when the transistor 210 is on, the transistor 212 is off and when the transistor 210 is off, the transistor 212 is on. The voltage of the square waveform 122 at the output O1 is V_{B}.

Each diode D1 and D2 protects a respective transistor 210 and 212 from excessive voltage. For example, the diode D1 protects the transistor 210 by acting as a short circuit when a voltage across the transistor 210 exceeds a predetermined threshold of the diode D1.

It should be noted that to achieve zero-voltage switching (ZVS), an impedance from the output O1 towards the point P1 and the load 108 (FIG. 1) is resistive or inductive.

In one embodiment, the DVS 116 excludes the capacitor 202.

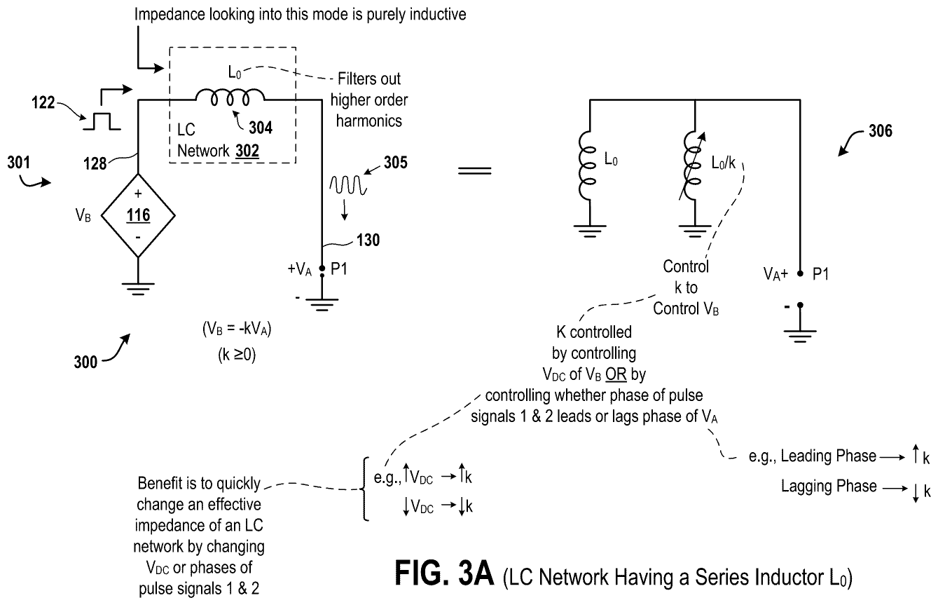

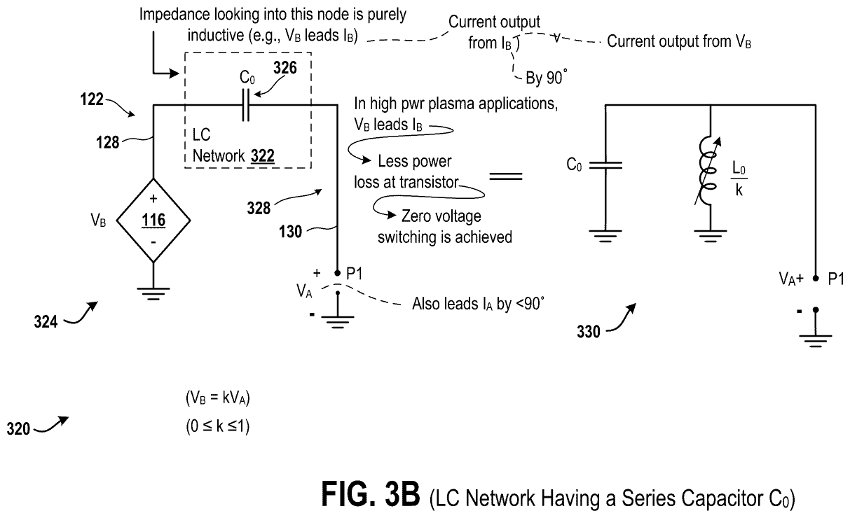

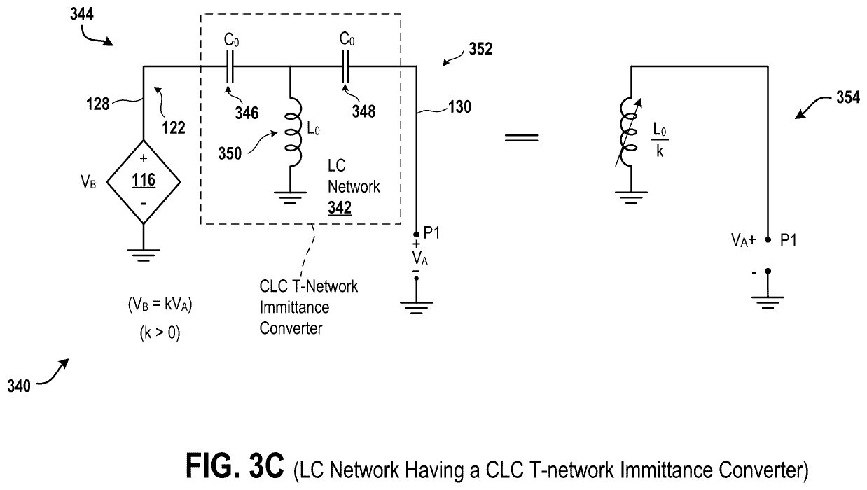

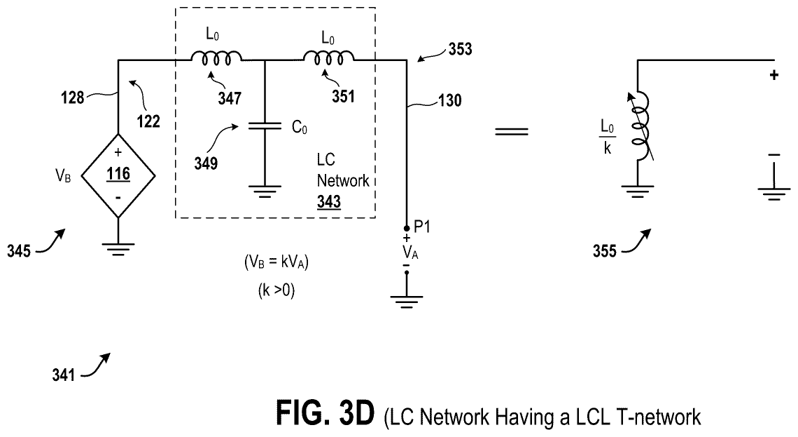

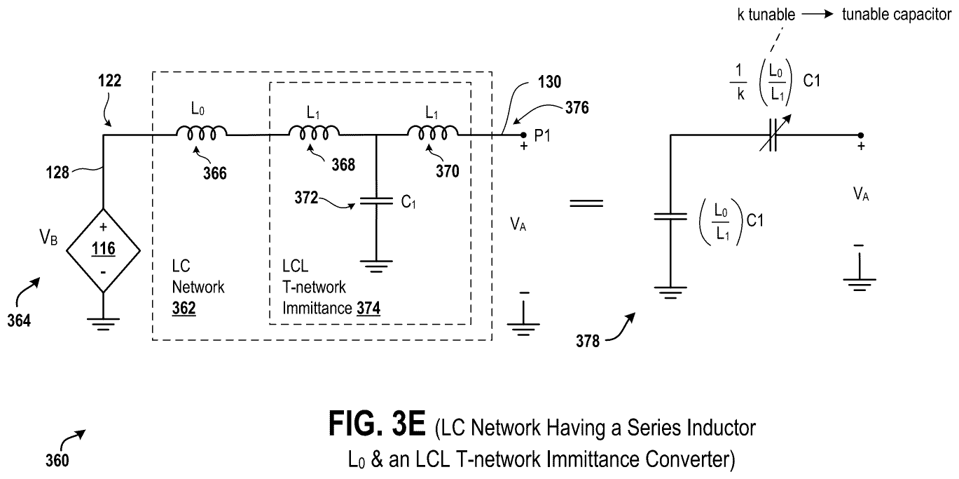

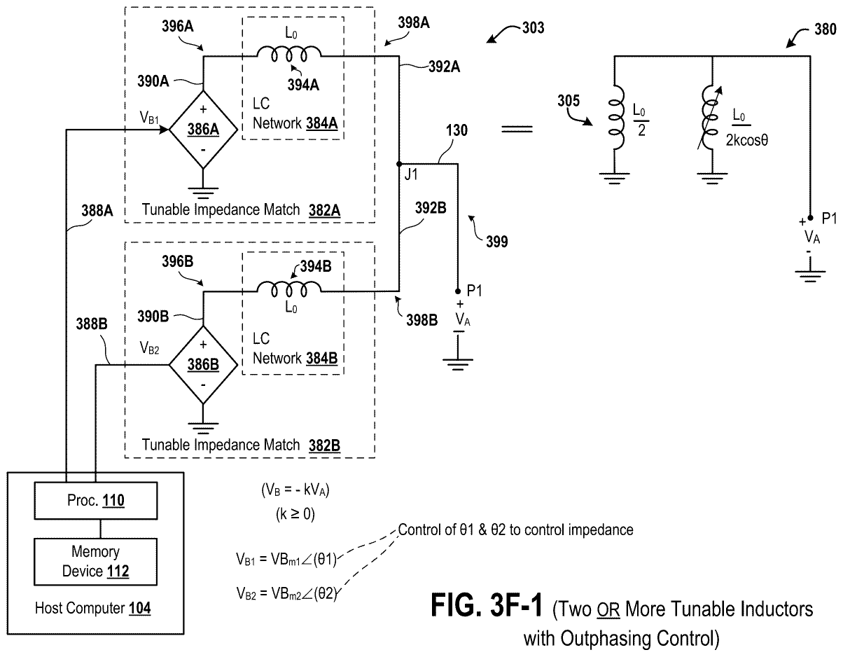

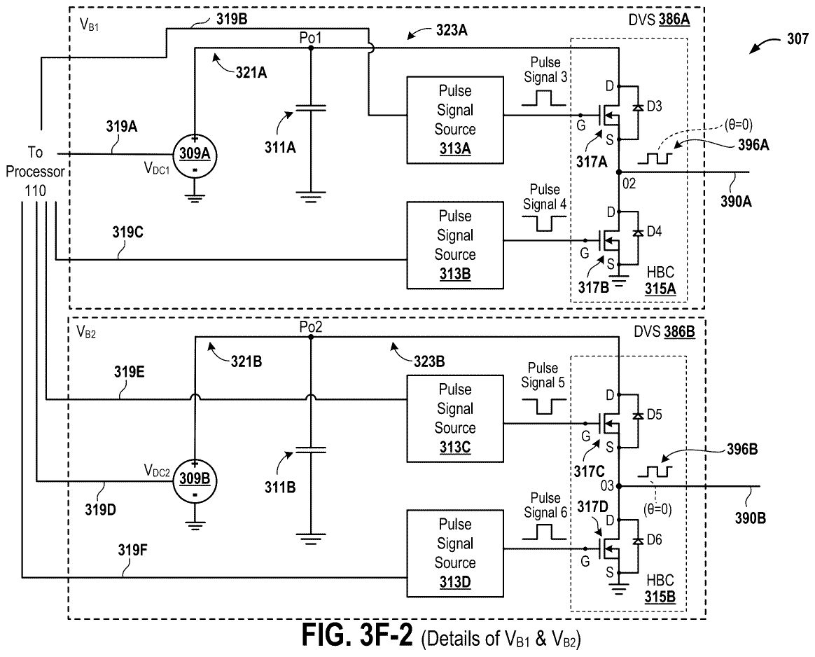

FIG. 3A is a diagram of an embodiment of a system 300 to illustrate an LC network 302. The LC network 302 is an example of the LC network 114 (FIG. 1). The system 300 includes a circuit 301, which includes the DVS 116 and the LC network 302. The LC network 302 includes an inductor 304 having an inductance L₀. The DVS 116 is coupled to the inductor 304 via the RF connection 128. The inductor 304 is coupled to the RF connection 130. The DVS 116 generates the square waveform 122 and sends the square waveform 122 to the inductor 304. The inductor 304 reduces, such as removes, harmonic frequencies of the square waveform 122 to output a modified waveform 305, which is an example of the modified waveform 124 (FIG. 1).

By controlling the amplitude V_{DC} of the voltage signal 218 (FIG. 2), a variable k is controlled. For example, the processor 110 (FIG. 1) modifies, such as increases or decreases, the amplitude V_{DC} that is provided to the DC voltage source 200 (FIG. 2) to increase or decrease the amplitude V_{DC} of the voltage signal 218. The amplitude V_{DC} is increased to increase a value of the variable k and is decreased to decrease a value of the variable k.

Moreover, the processor 110 controls the phases of the pulse signals 1 and 2 (FIG. 2) to increase or decrease the value of the variable k. For example, the processor 110 provides the phases of the pulse signals 1 and 2 to the pulse signal sources 204 and 206 (FIG. 2) to lead a phase of the voltage V_{A} to increase the value of the variable k. The processor 110 provides the phases of the pulse signals 1 and 2 to the pulse signal sources 204 and 206 to lag the phase of the voltage V_{A} to decrease the value of the variable k. By controlling the amplitude V_{DC} or by controlling the phases of the pulse signals 1 and 2 or by controlling the amplitude V_{DC} and by controlling the phases of the pulse signals 1 and 2, the variable k is controlled, such as modified, in a quick and efficient manner. By modifying the variable k, an impedance of the square waveform 122 is modified quickly to modify an impedance of the modified waveform 305. Also, by controlling the controlling the amplitude V_{DC} and/or by controlling the phases of the pulse signals 1 and 2 to output the modified waveform 305, an impedance of the RF signal 120 (FIG. 1) is modified in a fast manner by the modified waveform 305 to modify an impedance of the RF signal 132 (FIG. 1).

When the LC network 302 includes the inductor 304, the variable k is a negative value of a ratio between the voltages V_{B} and V_{A}, and k is greater than or equal to zero. For example, V_{B}=−kV_{A}, and k≥0. By controlling, such as increasing or decreasing, the value of the variable k, the voltage V_{B} is controlled. For example, when the value of the variable k increases, an amplitude of the voltage V_{B} decreases and when the value of the variable k decreases, the amplitude of the voltage V_{B} increases. The circuit 301 is equivalent to another circuit 306 having the inductance L₀ in parallel with an inductance L₀/k. It should be noted that an impedance from the standpoint of the DVS 116 is inductive. For example, the impedance from the standpoint of the DVS 116 is purely inductive to achieve ZVS.

In an embodiment, the DVS 116 (FIG. 2) excludes the DC voltage source 200 (FIG. 2). In the embodiment, the capacitor 202 is included. Also, in the embodiment, the processor 110 modifies the variable k by controlling the phases of the pulse signals 1 and 2 in the manner described herein. There is no control of the DC voltage source 200 to control the variable k.

In one embodiment, the processor 110 modifies the variable k by controlling the DC voltage source 200 in the manner described herein. In the embodiment, the variable k is not controlled by controlling the phases of the pulse signals 1 and 2.

FIG. 3B is a diagram of an embodiment of a system 320 to illustrate an LC network 322. The LC network 322 is an example of the LC network 114 (FIG. 1). The system 320 includes a circuit 324, which includes the DVS 116 and the LC network 322. The LC network 322 includes a capacitor 326 having a capacitance C₀. The DVS 116 is coupled to the capacitor 326 via the RF connection 128. The capacitor 326 is coupled to the RF connection 130. The DVS 116 generates the square waveform 122 and sends the square waveform 122 to the capacitor 326. The capacitor 326 reduces, such as removes, harmonic frequencies of the square waveform 122 to output a modified waveform 328, which is an example of the modified waveform 124 (FIG. 1).

By controlling the amplitude V_{DC} or by controlling the phases of the pulse signals 1 and 2 or by controlling the amplitude V_{DC} and by controlling the phases of the pulse signals 1 and 2, the variable k is controlled in a quick and efficient manner. By modifying the variable k, an impedance of the square waveform 122 is modified quickly to control, such as modify, an impedance of the modified waveform 328. Also, by controlling the amplitude V_{DC} and/or by controlling the phases of the pulse signals 1 and 2 to output the modified waveform 328, an impedance of the RF signal 120 (FIG. 1) is modified in a fast manner by the modified waveform 328 to modify an impedance of the RF signal 132 (FIG. 1).

When the LC network 322 includes the capacitor 326, the variable k is a value of a ratio between the voltages V_{B} and V_{A}, and k is greater than or equal to zero and less than or equal to 1. For example, V_{B}=kV_{A}, and 0≤k≤1. By controlling, such as increasing or decreasing, the value of the variable k, the voltage V_{B} is controlled. For example, when the value of the variable k increases, an amplitude of the voltage V_{B} increases and when the value of the variable k decreases, the amplitude of the voltage V_{B} decreases. The circuit 324 is equivalent to another circuit 330 having the capacitance C₀ in parallel with the inductance L₀/k.

It should be noted that an impedance from the standpoint of the DVS 116 is inductive, such as only or purely inductive. For example, a phase of the voltage V_{B} leads a phase of a current I_{B} by 90 degrees. The current I_{B} is output from the DVS 116 based on the voltage V_{B}. In high power plasma applications, when the phase of the voltage V_{B} leads the phase of the current I_{B}, power loss at the transistors 210 and 212 (FIG. 2) decreases, and ZVS is achieved.

FIG. 3C is a diagram of an embodiment of a system 340 to illustrate an LC network 342. The LC network 342 is an example of the LC network 114 (FIG. 1). The system 340 includes a circuit 344, which includes the DVS 116 and the LC network 342. The LC network 342 includes a capacitor 346 having the capacitance C₀, an inductor 350 having the inductance L₀, and another capacitor 348 having the capacitance C₀. The LC network 342 is a CLC T-network immittance converter.

The DVS 116 is coupled to the capacitor 346 via the RF connection 128. The capacitor 346 is coupled to the inductor 350 and to the capacitor 348. The capacitor 348 is coupled to the RF connection 130. The DVS 116 generates the square waveform 122 and sends the square waveform 122 to the LC network 342. The LC network 342 reduces, such as removes, harmonic frequencies of the square waveform 122 to output a modified waveform 352, which is an example of the modified waveform 124 (FIG. 1).

By controlling the amplitude V_{DC} or by controlling the phases of the pulse signals 1 and 2 or by controlling the amplitude V_{DC} and by controlling the phases of the pulse signals 1 and 2, the variable k is modified quickly in an efficient manner. By modifying the variable k, an impedance of the square waveform 122 is modified quickly to modify an impedance of the modified waveform 352. Also, by controlling the amplitude V_{DC} and/or by controlling the phases of the pulse signals 1 and 2 to control the impedance of the modified waveform 352, an impedance of the RF signal 120 (FIG. 1) is modified in a fast manner by the modified waveform 352 to control an impedance of the RF signal 132 (FIG. 1).

When the LC network 342 is used, the variable k is a value of a ratio between the voltages V_{B} and V_{A}, and k is greater than zero. For example, V_{B}=kV_{A}, and k>0. By controlling, such as increasing or decreasing, the value of the variable k, the voltage V_{B} is controlled. For example, when the value of the variable k increases, an amplitude of the voltage V_{B} increases and when the value of the variable k decreases, the amplitude of the voltage V_{B} decreases. The circuit 344 is equivalent to another circuit 354 having the inductance L₀/k. It should be noted that an impedance from the standpoint of DVS 116 towards the point P1 is inductive to achieve ZVS.

In an embodiment, the capacitor 346 has a different capacitance than that of the capacitor 348.

FIG. 3D is a diagram of an embodiment of a system 341 to illustrate an LC network 343. The LC network 343 is an example of the LC network 114 (FIG. 1). The system 341 includes a circuit 345, which includes the DVS 116 and the LC network 343. The LC network 343 includes an inductor 347 having the inductance L₀, a capacitor 349 having the capacitance C₀, and another inductor 351 having the inductance L₀. The LC network 343 is an LCL T-network immittance converter.

The DVS 116 is coupled to the inductor 347 via the RF connection 128. The inductor 347 is coupled to the capacitor 349 and to the inductor 351. The inductor 351 is coupled to the RF connection 130. The DVS 116 generates the square waveform 122 and sends the square waveform 122 to the LC network 343. The LC network 343 reduces, such as removes, harmonic frequencies of the square waveform 122 to output a modified waveform 353, which is an example of the modified waveform 124 (FIG. 1).

By controlling the amplitude V_{DC} or by controlling the phases of the pulse signals 1 and 2 or by controlling the amplitude V_{DC} and by controlling the phases of the pulse signals 1 and 2, the variable k is modified quickly in an efficient manner. By modifying the variable k, an impedance of the square waveform 122 is modified quickly to modify an impedance of the modified waveform 353. Also, by the amplitude V_{DC} and/or by controlling the phases of the pulse signals 1 and 2 to control, such as modify, the impedance of the modified waveform 353, an impedance of the RF signal 120 (FIG. 1) is modified in a fast manner by the modified waveform 353 to control an impedance of the RF signal 132 (FIG. 1).

When the LC network 343 is used, the variable k is a negative of a value of a ratio between the voltages V_{B} and V_{A}, and k is greater than zero. For example, V_{B}=−kV_{A}, and k>0. By controlling, such as increasing or decreasing, the value of the variable k, the voltage V_{B} is controlled. For example, when the value of the variable k increases, an amplitude of the voltage V_{B} decreases and when the value of the variable k decreases, the amplitude of the voltage V_{B} increases. The circuit 341 is equivalent to another circuit 355 having the inductance L₀/k.

In an embodiment, the inductor 347 has a different inductance than that of the inductor 351.

FIG. 3E is a diagram of an embodiment of a system 360 to illustrate an LC network 362. The LC network 362 is an example of the LC network 114 (FIG. 1). The system 360 includes a circuit 364, which includes the DVS 116 and the LC network 362. The LC network 362 includes an inductor 366 having the inductance L₀, an inductor 368 having an inductance L₁, another inductor 370 having the inductance L₁, and a capacitor 372 having the capacitance C₁. The inductors 368 and 370 and the capacitor 372 form an LCL T-network immittance converter 374.

The DVS 116 is coupled to the inductor 366 via the RF connection 128. The inductor 366 is coupled to the inductor 368, which is coupled to the inductor 370 and to the capacitor 372. The inductor 370 is coupled to the RF connection 130. The DVS 116 generates the square waveform 122 and sends the square waveform 122 to the LC network 362. The LC network 362 reduces, such as removes, harmonic frequencies of the square waveform 122 to output a modified waveform 376, which is an example of the modified waveform 124 (FIG. 1).

By controlling the amplitude V_{DC} or by controlling the phases of the pulse signals 1 and 2 or by controlling the amplitude V_{DC} and by controlling the phases of the pulse signals 1 and 2, the variable k is modified quickly in an efficient manner. By modifying the variable k, an impedance of the square waveform 122 is modified quickly to modify an impedance of the modified waveform 376. By controlling the controlling the amplitude V_{DC} and/or by controlling the phases of the pulse signals 1 and 2 to output the modified waveform 376, an impedance of the RF signal 120 (FIG. 1) is modified in a fast manner by the modified waveform 376 to control, such as modify, an impedance of the RF signal 120 (FIG. 1). The impedance of the RF signal 120 is modified to control an impedance of the RF signal 132 (FIG. 1). The circuit 344 is equivalent to another circuit 378 having a series coupling between a capacitance (L₀/L₁)C₁ and an inductance L₀C₁/kL₁.

In an embodiment, the inductor 368 has a different inductance than an inductance of the inductor 370.

FIG. 3F-1 is a diagram of an embodiment of the system 380 to illustrate use of multiple tunable impedance matches 382A and 382B. The system 380 includes the tunable impedance matches 382A and 382B and the host computer 104.

The tunable impedance match 382A includes an LC network 384A and a DVS 386A. The LC network 384A includes an inductor 394A having the inductance L₀. The processor 110 is coupled to the DVS 386A via a transfer cable 388A. The DVS 386A is coupled to the LC network 384A via an RF connection 390A to be coupled in series with the LC network 384A. The LC network 384A is coupled to a junction J1 via an RF connection 392A, and the junction J1 is coupled to the point P1 via the RF connection 130.

Also, the tunable impedance match 382B includes an LC network 384B and a DVS 386B. The LC network 384B includes an inductor 394B having the inductance L₀. The processor 110 is coupled to the DVS 386B via a transfer cable 388B. The DVS 386B is coupled to the LC network 384B via an RF connection 390B to be coupled in series with the LC network 384B. The LC network 384B is coupled to the junction J1 via an RF connection 392B.

A circuit 303 is equivalent to another circuit 305 having a parallel coupling between an inductance L₀/2 and another inductance L₀/(2kcosθ), where θ is a phase of the voltage V_{B}. The circuit 303 includes the DVSs 386A and 386B, the LC networks 384A and 384B, and the junction J1.

The processor 110 controls the DVS 386A to generate a square waveform 396A at the radio frequency. The DVS 386A generates the square waveform 396A and supplies the square waveform 396A to the LC network 384A. The LC network 384A reduces, such as removes, harmonics of the square waveform 396A to output a modified waveform 398A, and provides the modified waveform 398A to the junction J1. The modified waveform 398A has a sinusoidal shape. When the square waveform 396A is generated, a voltage at the DVS 386A with respect to the ground potential is V_{B1}. For example, a voltage of the square waveform 396A is V_{B1}. The voltage V_{B1} has a magnitude V_{Bm1} and a phase θ1. The processor 110 controls, such as modifies, the magnitude V_{Bm1} or the phase θ1 or both the magnitude V_{Bm1} and the phase θ1 to control the DVS 386A. The DVS 386A is controlled to modify an impedance of the square waveform 396A to further control, such as modify, an impedance of the modified waveform 398A.

Also, the processor 110 controls the DVS 386B to generate a square waveform 396B at the radio frequency. The DVS 386B generates the square waveform 396B and supplies the square waveform 396B to the LC network 384B. The LC network 384B reduces, such as removes, harmonics of the square waveform 396B to output a modified waveform 398B, and provides the modified waveform 398B to the junction J1. The modified waveform 398B has a sinusoidal shape. When the square waveform 396B is generated, a voltage at the DVS 386B with respect to the ground potential is V_{B2}. For example, a voltage of the square waveform 396B is V_{B2}. The voltage V_{B2} has the magnitude V_{Bm2} and a phase θ2. For example, the phase of the voltage V_{B2} is the same as or 180 degrees out-of-phase with the phase of voltage V_{B1}. The processor 110 controls, such as modifies, the magnitude V_{Bm2} or the phase θ2 or both the magnitude V_{Bm2} and the phase θ2 to control the DVS 386B. The DVS 386B is controlled to modify an impedance of the square waveform 396B to further control, such as modify, an impedance of the modified waveform 398B.

The modified waveform 398A is combined with the modified waveform 398B at the junction J1 to generate a modified waveform 399, which is provided to the point P1. By controlling one or more of the magnitudes V_{Bm1} and V_{Bm2} and the phases θ1 and θ2 of the voltages V_{B1} and V_{B2}, an impedance of the modified waveform 399 is controlled. The modified waveform 399 is an example of the modified waveform 124 (FIG. 1). By controlling the impedance of the modified waveform 399, an impedance of the RF signal 120 (FIG. 1) is modified in a fast manner to modify an impedance of the RF signal 132 (FIG. 1).

In an embodiment, instead of the LC network 384A, the LC network 322 (FIG. 3B), the LC network 342 (FIG. 3C), the LC network 343 (FIG. 3D), or the LC network 362 (FIG. 3E) is used. Similarly, in one embodiment, instead of the LC network 384B, the LC network 322, the LC network 342, the LC network 343, or the LC network 362 is used.

In one embodiment, an inductance of the inductor 394A is different from an inductance of the inductor 394B.

FIG. 3F-2 is a diagram of an embodiment of a system 307 that includes the DVS 386A and the DVS 386B. The DVS 386A includes a DC voltage source 309A, a capacitor 311A, a pulse signal source 313A, another pulse signal source 313B, and an HBC 315A. The HBC 315A includes a transistor 317A, another transistor 317B, a diode D3, and another diode D4. Each transistor 317A and 317B is a MOSFET, and has a gate (G), a source(S), and a drain (D).

The DC voltage source 309A is coupled via a transfer cable 319A to the processor 110. Also, the DC voltage source 309A is coupled via a point Pol to the capacitor 311A and via the point Pol to the drain of the transistor 317A. Another end of the DC voltage source 309A is coupled to the ground potential. The capacitor 311A is coupled at one end to the DC voltage source 309A and at an opposite end to the ground potential.

The source of the transistor 317A is coupled to an output O2, which is coupled to the RF connection 390A. The output O2 is coupled to the drain of the transistor 317B and the source S of the transistor 317B is coupled to the ground potential. Because the DC voltage source 309A, the capacitor 311A, and the HBC 315A are coupled to the same point Pol and to the ground potential, the DC voltage source 309A, the capacitor 311A, and the HBC 315A are coupled to each other in parallel. The pulse signal source 313A is coupled to the processor 110 via a transfer cable 319B and is coupled to the gate of the transistor 317A. Also, the pulse signal source 313B is coupled to the processor 110 via a transfer cable 319C and is coupled to the gate of the transistor 317B.

The processor 110 controls the pulse signal source 313A to generate a pulse signal 3. For example, the processor 110 provides a frequency, a phase, and a duty cycle to the pulse signal source 313A via the transfer cable 319B. Upon receiving the frequency, the phase, and the duty cycle, the pulse signal source 313A generates the pulse signal 3 having the duty cycle, the phase, and the frequency, and sends the pulse signal 3 to the gate of the transistor 317A.

Similarly, upon receiving a duty cycle, phase, and a frequency via a transfer cable 319C from the processor 110, the pulse signal source 313B generates a pulse signal 4 having the duty cycle, the phase, and the frequency, and sends the pulse signal 4 to the gate of the transistor 317B. The phases of the pulse signals 3 through 4 are controlled by the processor 110 to control the phase of the square waveform 396A. The processor 110 controls the pulse signal 4 to be in reverse synchronization with the pulse signal 3. For example, the processor 110 provides the phase of the pulse signal 4 to be 180 degrees out of phase with the phase of the pulse signal 3. The phase of the pulse signal 4 is provided to the pulse signal source 313B.

The processor 110 controls the DC voltage source 309A to control an amplitude V_{DC1} of a voltage signal 321A. For example, the processor 110 provides the amplitude V_{DC1} to the DC voltage source 309A. Upon receiving the amplitude V_{DC1}, the DC voltage source 309A outputs the voltage signal 321A having the amplitude V_{DC1} towards the drain of the transistor 317A. The capacitor 311A filters out an AC signal from the voltage signal 321A to provide a voltage signal 323A to the drain of the transistor 317A.

The voltage signal 323A has the substantially the same, such as the same, amplitude as that of the voltage signal 321A. For example, the voltage signal 323A has the amplitude V_{DC1} that is equal to the amplitude of the voltage signal 321A. As another example, the voltage signal 323A has an amplitude that is a difference between the amplitude V_{DC1} of the voltage signal 321A and amplitudes of the AC signal that is filtered out. When the voltage signal 323A is provided to the transistor 317A, the transistors 317A and 317B operate in a push-pull mode based on the pulse signals 3 and 4 to provide the square waveform 396A at the output O2. For example, in the push-pull mode, when the transistor 317A is on, the transistor 317B is off and when the transistor 317A is off, the transistor 317B is on. The voltage of the square waveform 396A at the output O2 is V_{B1}.

Each diode D3 and D4 protects a respective transistor 317A and 317B from excessive voltage. For example, the diode D3 protects the transistor 317A by acting as a short circuit when a voltage across the transistor 317A exceeds a predetermined threshold of the diode D3.

The DVS 386B includes a DC voltage source 309B, a capacitor 311B, a pulse signal source 313C, another pulse signal source 313D, and an HBC 315B. The HBC 315B includes a transistor 317C, another transistor 317D, a diode D5, and another diode D6. Each transistor 317C and 317D is a MOSFET, and has a gate (G), a source(S), and a drain (D).

The DC voltage source 309B is coupled via a transfer cable 319D to the processor 110. Also, the DC voltage source 309B is coupled via a point Po2 to the capacitor 311B and via the point Po2 to the drain of the transistor 317C. Another end of the DC voltage source 309B is coupled to the ground potential. The capacitor 311B is coupled at one end to the DC voltage source 309B and at an opposite end to the ground potential.

The source of the transistor 317C is coupled to an output O3, which is coupled to the RF connection 390B. The output O3 is coupled to the drain of the transistor 317D and the source S of the transistor 317D is coupled to the ground potential. Because the DC voltage source 309B, the capacitor 311B, and the HBC 315B are coupled to the same point Po2 and to the ground potential, the DC voltage source 309B, the capacitor 311B, and the HBC 315B are coupled to each other in parallel. The pulse signal source 313C is coupled to the processor 110 via a transfer cable 319E and is coupled to the gate of the transistor 317C. Also, the pulse signal source 313D is coupled to the processor 110 via a transfer cable 317F and is coupled to the gate of the transistor 317D.

The processor 110 controls the pulse signal source 313C to generate a pulse signal 5. For example, the processor 110 provides a frequency, a phase, and a duty cycle to the pulse signal source 313C via the transfer cable 319E. Upon receiving the frequency, the phase, and the duty cycle, the pulse signal source 313C generates the pulse signal 5 having the duty cycle, the phase, and the frequency, and sends the pulse signal 5 to the gate of the transistor 317C.

Similarly, upon receiving a duty cycle, a phase, and a frequency via a transfer cable 319F from the processor 110, the pulse signal source 313D generates a pulse signal 6 having the duty cycle, the phase, and the frequency. The phases of the pulse signals 5 through 6 are controlled by the processor 110 to control the phase of the square waveform 396B. The processor 110 controls the pulse signal 6 to be in reverse synchronization with the pulse signal 53. For example, the processor 110 provides the phase of the pulse signal 6 to be 180 degrees out of phase with the phase of the pulse signal 5. The phase of the pulse signal 6 is provided to the pulse signal source 313D. The pulse signal 6 is sent from the pulse signal source 313D to the gate of the transistor 317D.

The processor 110 controls the DC voltage source 309B to control an amplitude V_{DC2} of a voltage signal 321B. For example, the processor 110 provides the amplitude V_{DC2} to the DC voltage source 309B. Upon receiving the amplitude V_{DC2}, the DC voltage source 309B outputs the voltage signal 321B having the amplitude V_{DC2} towards the drain of the transistor 317C. The capacitor 311B filters out an AC signal from the voltage signal 321B to provide a voltage signal 323B to the drain of the transistor 317C.

The voltage signal 323B has the substantially the same, such as the same, amplitude as that of the voltage signal 321B. For example, the voltage signal 323B has the amplitude V_{DC2} that is equal to the amplitude of the voltage signal 321B. As another example, the voltage signal 323B has an amplitude that is a difference between the amplitude V_{DC2} of the voltage signal 321B and amplitudes of the AC signal that is filtered out. When the voltage signal 323B is provided to the transistor 317C, the transistors 317C and 317D operate in a push-pull mode based on the pulse signals 5 and 6 to generate the square waveform 396B at the output O3. For example, in the push-pull mode, when the transistor 317C is on, the transistor 317D is off and when the transistor 317C is off, the transistor 317D is on. The voltage of the square waveform 396B at the output O3 is V_{B2}.

Each diode D5 and D6 protects a respective transistor 317C and 317D from excessive voltage. For example, the diode D5 protects the transistor 317C by acting as a short circuit when a voltage across the transistor 317C exceeds a predetermined threshold of the diode D5.

In one embodiment, the DVS 386A excludes the capacitor 311A and the DVS 386B excludes the capacitor 311B.

In an embodiment, instead of an HBC, such as the HBC 208 (FIG. 2), the HBC 315A, or the HBC 315B, another inverter circuit is used. For example, a first full-bridge circuit is used in place of the HBC 315A and a second full-bridge circuit is used in place of the HBC 315B. As another example, a full-bridge circuit is used in place of the HBC 208. Examples of the other inverter circuit include a full-bridge circuit, a class-E circuit, and any other switched-mode power inverter.

In one embodiment, the terms inverter circuit and rectifier circuit are used herein interchangeably.

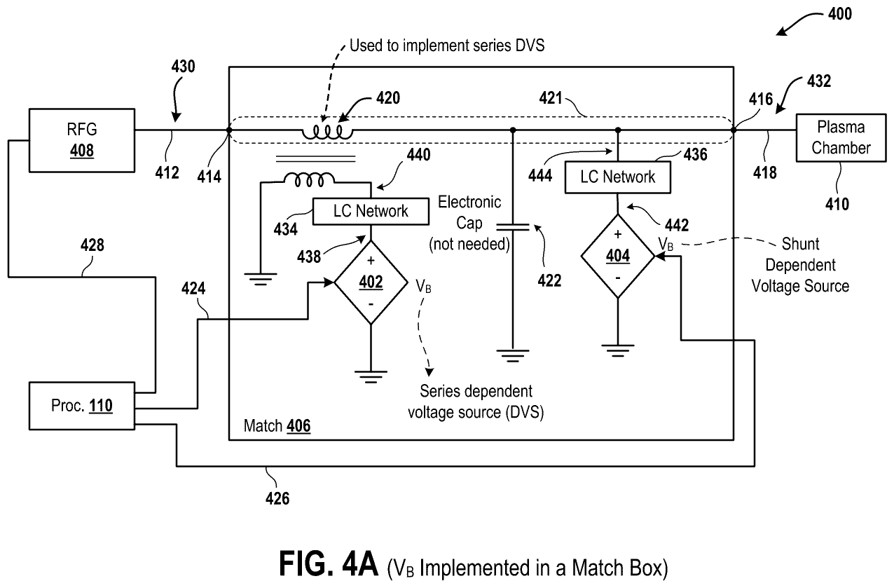

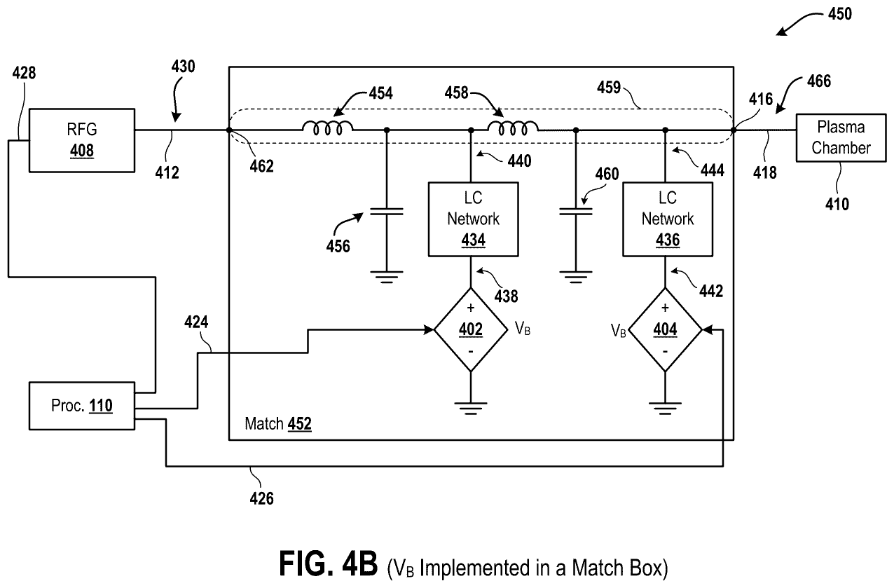

FIG. 4A is a diagram of an embodiment of a system 400 to illustrate use of multiple DVSs 402 and 404 within a match 406. The DVS 402 is a series DVS and the DVS 404 is a shunt DVS. The DVS 116 (FIG. 2) is an example of the DVS 402. Also, the DVS 116 is an example of the DVS 404. The system 400 includes an RF generator 408, the match 406, and a plasma chamber 410. An example of the RF generator 408 is an RF generator that has a low frequency of operation, a medium frequency of operation, or a high frequency of operation. An example of the low frequency of operation is 400 kilohertz (kHz) or 2 megahertz (MHz). An example of the medium frequency of operation is 27 MHz and an example of the high frequency of operation is 60 MHz. The RF generator 408 is an example of the plasma source 106 (FIG. 1) and the plasma chamber 410 is an example of the load 108 (FIG. 1).

The match 406 includes the DVS 402, a transformer 420, a capacitor 422, the DVS 404, an LC network 434, and an LC network 436. An example of the LC network 434 includes the LC network 114 (FIG. 1) and an example of the LC network 436 includes the LC network 114. As an example, the match 406 does not include any mechanical components, such as mechanical inductors and mechanical capacitors. An example of a mechanical inductor is a coil and a core that passes through the coil. The core is movable with respect to the coil by a motor. An example of a mechanical capacitor is a fixed plate and a movable plate that is separated by a distance from the fixed plate. The movable plate is rotatable with respect to fixed plate by a motor.

The capacitor 422 is an electronic capacitor. For example, the capacitor 422 is not a mechanical capacitor. As an example, an electronic capacitor is an integrated circuit or a ceramic capacitor. The DVS 402 is coupled to the LC network 434, which is coupled to a primary winding of the transformer 420 and the input 414 is coupled to a secondary winding of the transformer 420. The secondary winding of the transformer 420 is coupled via an RF path 421 to the capacitor 422 and via the RF path 421 to the input 414 of the match 406. The RF path 421 extends from the input 414 to the output 416. The capacitor 422 is a shunt circuit. The DVS 404 is coupled to the LC network 436, and the LC network 436 is coupled to an output 416 of the match 406 via the RF path 421. Also, a combination of the DVS 404 and the LC network 436 forms a shunt circuit. The secondary winding forms a part of the RF path 421. An RF path, as used herein, includes one or more RF connections, and one or more match network components, such as an inductor or a capacitor or a winding of a transformer.

The RF generator 408 is coupled via an RF cable 412, such as a 50 ohm RF cable, to the input 414 of the match 406. The output 416 of the match 406 is coupled via an RF transmission line 418 to the plasma chamber 410. An example of the RF transmission line 418 is a combination of an RF sheath that surrounds an RF rod. An insulator is placed between the RF rod and the RF sheath. The processor 110 is coupled via a transfer cable 424 to the DVS 402 and is coupled via a transfer cable 426 to the DVS 404. Also, the processor 110 is coupled via a transfer cable 428 to the RF generator 408.

The processor 110 controls the RF generator 408 to generate an RF signal 430. For example, the processor 110 provides a frequency and power of the RF signal 430 via the transfer cable 428 to the RF generator 408. Upon receiving the frequency and power, the RF generator 408 generates an RF signal 430, which is a sinusoidal signal, and sends the RF signal 430 via the RF cable 412 to the match 406.

While the RF signal 430 is transferred via the match 406, the processor 110 controls one or more of the DVSs 402 and 404 to output one or more square waveforms 438 and 442. For example, the processor 110 controls the DVS 402 to output the square waveform 438. The square waveform 438 is processed by the LC network 434 in a manner described above to output a modified waveform 440. A voltage of the modified waveform 440 is modified, such as increased or decreased, by the transformer 420 to output an amplified waveform. Similarly, the processor 110 controls the DVS 404 to output the square waveform 442. The square waveform 442 is processed by the LC network 436 in a manner described above to output a modified waveform 444.

The amplified waveform, the capacitor 422, and the modified waveform 444 modify an impedance of the RF signal 430. The impedance of the RF signal 430 is modified to match an impedance of a load coupled to the output 416 with an impedance of a source coupled to the input 414. An example of the load coupled to the output 416 includes the RF transmission line 418 and the plasma chamber 410, and an example of the source coupled to the input 414 includes the RF cable 412 and the RF generator 408. The impedance of the RF signal 430 is modified to output a modified RF signal 432 at the output 416. The modified RF signal 432 is sent via the RF transmission line 418 to an electrode, such as the ESC or the RF coil or the upper electrode, of the plasma chamber 410 to process the semiconductor substrate placed within the plasma chamber 410. By controlling one or more of the amplitude V_{DC} of the DVS 402, the amplitude V_{DC} of the DVS 404, the phases of the pulse signals 1 and 2 of the DVS 402, the phases of the pulse signals 1 and 2 of the DVS 404, an impedance of the RF signal 430 is modified in a fast manner to output the modified RF signal 432.

It should be noted that although potential of both the DVSs 402 and 404 is illustrated as being the same, such as V_{B}, a potential of the DVS 404 is different than a potential of the DVS 402.

In an embodiment, the match 406 excludes the DVS 402 or the DVS 404.

FIG. 4B is a diagram of an embodiment of a system 450 to illustrate use of the DVSs 402 and 404 within a match 452. The system 450 includes an RF generator 408, the match 452, and the plasma chamber 410.

The match 452 includes the DVS 402, an inductor 454, a capacitor 456, the DVS 404, the LC network 434, the LC network 436, an inductor 458, and a capacitor 460. As an example, the match 452 does not include any mechanical components.

Each capacitor 456 and 460 is an electronic capacitor. For example, the capacitor 456 is not a mechanical capacitor. Also, the inductor 458 is an electronic inductor. For example, the inductor 458 is not a mechanical inductor. As an example, an electronic inductor is an integrated circuit.

The inductor 454 is coupled to an input 462 of the match 452 via an RF path 459. The RF path 459 extends from the input 462 to an output 464 of the match 452. The inductor 454 is coupled to the capacitor 456 via the RF path 459, and to the inductor 458 via the RF path 459. The capacitor 456 is coupled to the LC network 434 via the RF path 459 and to the inductor 458 via the RF path 459. The LC network 434 is coupled to the inductor 458 via the RF path 459. The capacitor 460 is coupled to the LC network 436 via the RF path 459. The LC network 436 is coupled to the output 464 of the match 452 via the RF path 459. The capacitor 456 is a shunt circuit and so is the capacitor 460. A combination of the LC network 434 and the DVS 402 forms a shunt circuit and a combination of the LC network 436 and the DVS 404 forms a shunt circuit. The RF path 459 includes the inductors 454 and 458, and one or more RF connections.

The RF generator 408 is coupled via the RF cable 412 to the input 462 of the match 452. The output 464 of the match 452 is coupled via the RF transmission line 418 to the plasma chamber 410.

The RF generator 408 sends the RF signal 430 via the RF cable 412 to the match 452. While the RF signal 430 is transferred via the match 452, the processor 110 controls one or more of the DVSs 402 and 404 to output one or more of the square waveforms 438 and 442. Thereafter, the modified waveforms 440 and 444, the inductor 454, the capacitor 456, the inductor 458, and the capacitor 460 modify an impedance of the RF signal 430. The impedance of the RF signal 430 is modified to match an impedance of the load coupled to the output 464 with an impedance of the source coupled to the input 462. An example of the load coupled to the output 464 includes the RF transmission line 418 and the plasma chamber 410, and an example of the source coupled to the input 462 includes the RF cable 412 and the RF generator 408. The impedance of the RF signal 430 is modified to output a modified RF signal 466 at the output 464. The modified RF signal 466 is sent via the RF transmission line 418 to the electrode of the plasma chamber 410 to process the semiconductor substrate placed within the plasma chamber 410. By controlling one or more of the amplitude V_{DC} of the DVS 402, the amplitude V_{DC} of the DVS 404, the phases of the pulse signals 1 and 2 of the DVS 402, the phases of the pulse signals 1 and 2 of the DVS 404, an impedance of the RF signal 430 is modified in a fast manner to output the modified RF signal 466.

In one embodiment, instead of the inductor 458, a capacitor is used.

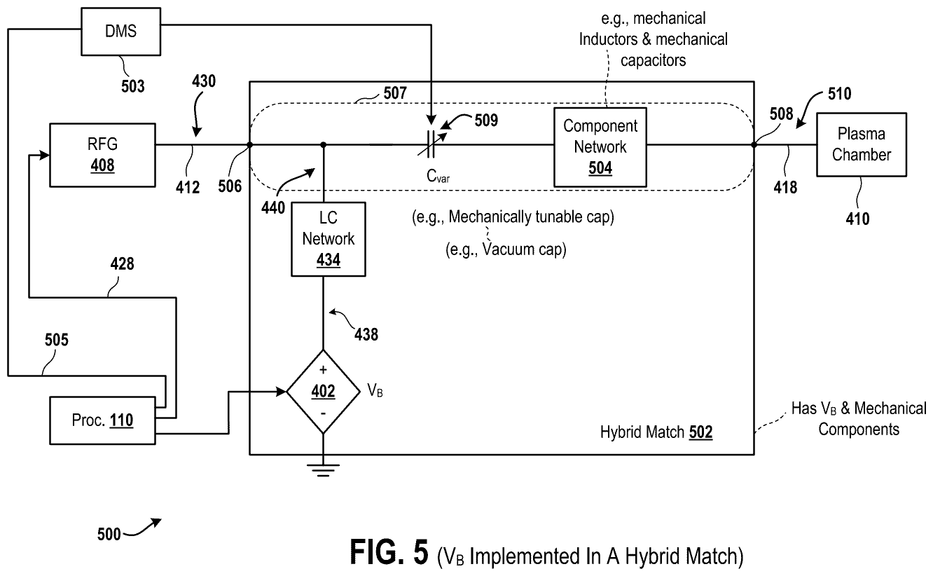

FIG. 5 is a diagram of an embodiment of a system 500 to illustrate use of the DVS 402 and the LC network 434 with the mechanical components. The system 500 includes the RF generator 408, a hybrid match 502, the plasma chamber 418, and a driver and motor system (DMS) 503.

The hybrid match 502 includes the DVS 402, the LC network 434, a component network 504, and a variable capacitor 509. The component network 504 includes one or more mechanical inductors, or one or more mechanical capacitors, or a combination thereof. In the component network 504, the mechanical inductors are coupled with each other, or the mechanical capacitors are coupled with each other, or the mechanical inductors are coupled with the mechanical capacitors. The DMS 503 includes a driver, such as one or more transistors, and an electric motor.

The RF generator 408 is coupled to an input 506 of the hybrid match 502 via the RF cable 412 and an output 508 of the hybrid match 502 is coupled to the electrode of the plasma chamber 410 via the RF transmission line 418. The LC network 434 is coupled to the variable capacitor 509 via an RF path 507 and to the input 506 via the RF path 507. The variable capacitor 509 is coupled to the component network 504 via the RF path 507, and the component network 504 is coupled to the output 508 via the RF path 507. The RF path 507 extends from the input 506 to the output 508, and includes the variable capacitor 509 and the component network 504.

The processor 110 is coupled to the driver via an RF connection 505, and the driver is coupled to the motor. The motor is coupled to the variable capacitor 509.

The RF generator 408 sends the RF signal 430 via the RF cable 412 to the hybrid match 502. While the RF signal 430 is transferred via the hybrid match 502, the processor 110 controls the DVS 402 to output the square waveform 438. Also, the processor 110 controls the variable capacitor 509 via the DMS 503 to modify a capacitance of the variable capacitor 509.

Thereafter, the modified waveform 440, the variable capacitor 509, and the component network 504 modify an impedance of the RF signal 430. The impedance of the RF signal 430 is modified to match an impedance of the load coupled to the output 508 with an impedance of the source coupled to the input 506. An example of the load coupled to the output 508 includes the RF transmission line 418 and the plasma chamber 410, and an example of the source coupled to the input 506 includes the RF cable 412 and the RF generator 408. The impedance of the RF signal 430 is modified to output a modified RF signal 510 at the output 508. The modified RF signal 510 is sent via the RF transmission line 418 to the electrode of the plasma chamber 410 to process the semiconductor substrate placed within the plasma chamber 410. By controlling one or more of the amplitude V_{DC} of the DVS 402 and the phases of the pulse signals 1 and 2 of the DVS 402, an impedance of the RF signal 430 is modified in a fast manner to output the modified RF signal 510.

In an embodiment, instead of the variable capacitor 509, a fixed mechanical capacitor, a variable mechanical inductor, or a fixed mechanical inductor is used.

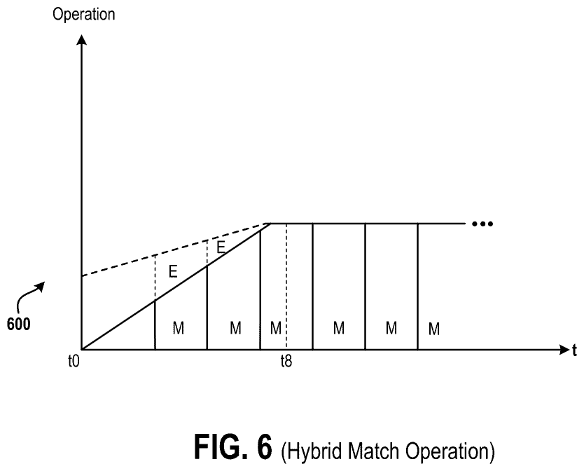

FIG. 6 is a diagram of an embodiment of a graph 600 to illustrate an operation of the hybrid match 502 (FIG. 5). The graph 600 plots an operation of the hybrid match 502 on a y-axis and time t on an x-axis. At a time to, both the mechanical components (M) and the electronic components (E) of the hybrid match 502 are controlled simultaneously by the processor 110 with the RF generator 408 (FIG. 5). The processor 110 controls the RF generator 408 to achieve a steady state of the RF signal 430 (FIG. 5) from the time to to a time between the time t0 and a time t8. The time t8 occurs after the time t0.

During a time period between the times t0 and t8, the processor 110 controls the mechanical and electronic components of the hybrid match 502. The electronic components of the hybrid match 502 facilitate matching of the impedance of the load with the impedance of the source faster than that facilitated by the mechanical components of the hybrid match 502. For example, at the time to, the mechanical components are non-operational and the electronic components are operational to achieve the matching. As time progresses from the time to to the time t8, the mechanical components become operational gradually to achieve the matching and the electronic components continue to achieve the matching at a rate faster than the mechanical components. At the time t8, the matching is achieved during the steady state of the RF generator 408. After the time t8, the mechanical components continue to achieve the matching.

In this manner, by controlling the mechanical components and electronic components to operate simultaneously within the hybrid match 502, high speed of achieving the impedance match between the load and the source is achieved with a low power loss. The electronic components are fast to tune but are more lossy compared to the mechanical components. The mechanical components are slow to tune but have a high quality (Q) factor to achieve precision in the impedance matching.

Broadly speaking, in a variety of embodiments, a controller, as used herein, is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A system for control of impedance associated with an output of a plasma source, comprising:
the plasma source configured to generate a radio frequency (RF) signal;
a load coupled to the plasma source via an RF connection, wherein the RF connection has a point;
a tunable impedance match coupled to the point between the plasma source and the load, wherein the tunable impedance match includes a dependent voltage source and a circuit network, wherein the dependent voltage source is coupled in series with the circuit network.

2. The system of claim 1, wherein the circuit network includes a capacitor or an inductor or a combination thereof, wherein the dependent voltage source includes a direct current (DC) voltage source, the system comprising a processor, wherein the processor is configured to modify a voltage output from the DC voltage source to achieve the control of impedance.

3. The system of claim 1, wherein the dependent voltage source includes a direct current (DC) voltage source and an inverter circuit, wherein the DC voltage source is coupled in parallel to the inverter circuit.

4. The system of claim 3, wherein the DC voltage source is configured to modify a voltage output from the DC voltage source for the control of impedance.

5. The system of claim 3, wherein the dependent voltage source includes a plurality of pulse signal sources including a first pulse source and a second pulse source, wherein the inverter circuit includes a first transistor and a second transistor, wherein the first pulse source is coupled to the first transistor to provide a first pulse signal to the first transistor and the second pulse source is coupled to the second transistor to provide a second pulse signal to the second transistor, wherein the first pulse source is configured to modify a phase of the first pulse signal and the second pulse source is configured to modify a phase of the second pulse signal to achieve the control of impedance.

6. The system of claim 5, wherein the second pulse signal is reversely synchronized with respect to the first pulse signal, wherein the phases of the first and second pulse signals are modified to lead a phase of a voltage at the point or to lag the phase of the voltage at the point to achieve the control of impedance.

7. The system of claim 1, wherein the dependent voltage source includes a capacitor and an inverter circuit, wherein the capacitor is coupled in parallel to the inverter circuit.

8. A system for control of impedance associated with an output of a plasma source, comprising:
the plasma source configured to generate a radio frequency (RF) signal;
a load coupled to the plasma source via an RF connection, wherein the RF connection has a point;
a plurality of tunable impedance matches coupled to the point between the plasma source and the load, wherein the plurality of tunable impedance matches include a first tunable impedance match and a second tunable impedance match, wherein the first tunable impedance matches includes a first dependent voltage source and a first circuit network, wherein the second tunable impedance matches includes a second dependent voltage source and a second circuit network, wherein the first dependent voltage source is coupled in series with the first circuit network, wherein the second dependent voltage source is coupled in series with the second circuit network.

9. The system of claim 8, wherein the first circuit network includes a first capacitor or a first inductor or a combination thereof, wherein the second circuit network includes a second capacitor or a second inductor or a combination thereof, wherein the plasma source is a matchless plasma source or a radio frequency (RF) generator, and the load includes a plasma chamber.

10. The system of claim 8, wherein the plurality of tunable impedance matches are configured to modify an impedance of the RF signal to output a modified RF signal, wherein the modified RF signal is provided to the load, wherein the RF signal is a sinusoidal signal and the load includes a plasma chamber.

11. The system of claim 8, wherein the first dependent voltage source includes a first pulse source and a second pulse source, wherein the second dependent voltage source includes a third pulse source and a fourth pulse source, wherein the first pulse source is configured to generate a first pulse signal and the second pulse source is configured to generate a second pulse signal, wherein the second pulse signal is reversely synchronized with the first pulse signal, wherein the third pulse source is configured to generate a third pulse signal and the fourth pulse source is configured to generate a fourth pulse signal, wherein the fourth pulse signal is reversely synchronized with the third pulse signal.

12. The system of claim 8, wherein the first dependent voltage source includes a first direct current (DC) voltage source, a first pulse source, a second pulse source, and a first inverter circuit, and the second dependent voltage source includes a second DC voltage source, a third pulse source, a fourth pulse source, and a second inverter circuit.

13. The system of claim 12, wherein the first DC voltage source is coupled in parallel with the first inverter circuit and the second DC voltage source is coupled in parallel with the second inverter circuit.

14. The system of claim 13, wherein the first dependent voltage source includes a first capacitor and the second dependent voltage source includes a second capacitor.

15. The system of claim 14, wherein the first capacitor is coupled in parallel with the first inverter circuit and the second capacitor is coupled in parallel with the second inverter circuit.

16. A system for control of impedance associated with an output of a radio frequency (RF) generator, comprising:
the RF generator configured to generate an RF signal;
a tunable impedance match coupled to the RF generator via an RF cable to receive the RF signal, wherein the tunable impedance match includes a dependent voltage source, wherein the tunable impedance match is configured to modify an impedance of the RF signal to output a modified RF signal; and
a load coupled to the tunable impedance match via an RF transmission line to receive the modified RF signal.

17. The system of claim 16, further comprising:
an additional tunable impedance match coupled to the RF generator via the RF cable, wherein the additional tunable impedance match includes an additional dependent voltage source, wherein the additional tunable impedance match is configured to modify the impedance of the RF signal to output the modified RF signal.

18. The system of claim 17, further comprising a match including the tunable impedance match, wherein the match includes a mechanical circuit component coupled to the tunable impedance match.

19. The system of claim 18, wherein the mechanical circuit component is a mechanical capacitor or a mechanical inductor.

20. The system of claim 16, wherein the tunable impedance match includes an inductor-capacitor network that is coupled to the dependent voltage source.
